(19) United States
(12) Patent Application Publication
(10) Pub. No.: US 2016/0300638 A1
(43) Pub. Date: Oct. 13, 2016

(54) Article with Composite Shield and Process of Producing an Article with a Composite Shield

(71) Applicants: Tyco Electronics Corporation, Berwyn, PA (US); Tyco Electronics UK Ltd., Swindon (GB)

(72) Inventors: Jialing Wang, Mountain View, CA (US); Erling Hansen, Redwood City, CA (US); Mark F. Wartenberg, Redwood City, CA (US); Jennifer L. Robison, San Mateo, CA (US); Sreeni Kurup, Swindon (GB); Richard B. Lloyd, Sunnyvale, CA (US); Ting Gao, Palo Alto, CA (US)

(73) Assignees: Tyco Electronics Corporation, Berwyn, PA (US); Tyco Electronics UK Ltd., Swindon (GB)

(21) Appl. No.: 14/684,266

(22) Filed: Apr. 10, 2015

(51) Int. Cl. H01B 1/24; H01B 1/22; H05K 9/00; B29C 47/00; B29C 47/06

(52) U.S. Cl. CPC H01B 1/24; B29C 47/0004; B29C 47/0026; B29C 47/065; H05K 9/0098; H01B 1/22; B29K 2105/0023

(57) ABSTRACT

An article and process are described. The article includes a conductive heat-recoverable composite shield or a conductive heat-recovered composite shield formed from a conductive heat-recoverable composite shield. The conductive composite shield and/or the conductive heat-recovered composite shield formed from a conductive heat-recoverable composite shield comprises a non-conductive matrix and conductive particles within the non-conductive matrix. The article has a resistivity of less than 0.05 ohm·cm. A process of producing the conductive heat-recovered composite shield includes extruding the conductive heat-recoverable composite shield and heating the conductive heat-recoverable composite shield thereby forming the conductive heat-recovered composite shield.

### FIELD OF THE INVENTION

The present invention is directed to articles with composite shields and processes of producing such articles. More particularly, the present invention is directed to heat-recoverable and heat-recovered composite shields.

### BACKGROUND OF THE INVENTION

In general, cable shielding materials can be metallic or include ferrites. Metallic shields come in the form of braids, tapes, tubular, spiral, knitted wire mesh with a plastic cover, laminates, plated yarns and fabrics, and many more arrangements. Such shields provide shielding effect for low frequency applications, but they have several drawbacks. For example, braids have diminishing shielding effectiveness in high frequency ranges due to poor optical coverage. Metallic shields can be heavy and/or require costly and complex plating processes. Ferrite beads are used for high frequency noise suppression, but they can be limited by the frequency range that the specific type of ferrite allows and are not suitable for high frequency signal devices.

Conductive shrinkable shields in the form of a regular heat-shrink tubing and a conductive inner layer, such as a metalized fabric layer or silver or silver-coated copper ink or paste, can be used in shielding. Such shielding is expensive, has poor adhesion, has inhomogeneity, does not fit with certain shape objects to be shielded, and is often difficult to terminate and ground.

An article with a composite shield and a process of producing an article with a composite shield that show one or more improvements in comparison to the prior art would be desirable in the art.

### BRIEF DESCRIPTION OF THE INVENTION

In an embodiment, an article includes a conductive heat-recoverable composite shield. The conductive composite shield comprises a non-conductive matrix and conductive particles within the non-conductive matrix. The article has a resistivity of less than 0.05 ohm·cm.

In another embodiment, an article includes a conductive heat-recovered composite shield formed from a conductive heat-recoverable composite shield. The heat-recoverable conductive composite shield comprises a non-conductive matrix and conductive particles within the non-conductive matrix. The article has a resistivity of less than 0.05 ohm·cm.

In another embodiment, a process of producing a conductive heat-recovered composite shield includes extruding a conductive heat-recoverable composite shield and heating the conductive heat-recoverable composite shield thereby forming the conductive heat-recovered composite shield. The heat-recoverable conductive composite shield comprises a non-conductive matrix and conductive particles within the non-conductive matrix. The article has a resistivity of less than 0.05 ohm·cm.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a schematic view of an embodiment a process of producing co-extruded conductive heat-recovered composite shield formed by heating an embodiment of conductive heat-recoverable composite shield, according to the disclosure.

FIG. 2 is a schematic view of an embodiment a process of producing tandem-extruded conductive heat-recovered composite shield formed by heating an embodiment of conductive heat-recoverable composite shield, according to the disclosure.

FIG. 3 is a graphical representation of tensile strength on the y-axis in MPa versus elongation of heat-recoverable composite shield on the x-axis in percent, according to embodiments of the disclosure.

FIG. 4 is a graphical representation of shielding effectiveness on the y-axis in dB of a heat-recoverable composite shield and frequency on the x-axis in GHz, according to an embodiment of the disclosure.

FIG. 5 is a graphical comparative representation of resistivity and contact resistance of an embodiment of a heat-recoverable composite shield, according to the disclosure.

Wherever possible, the same reference numbers will be used throughout the drawings to represent the same parts.

### DETAILED DESCRIPTION OF THE INVENTION

Provided are an article with a composite shield and a process of producing an article with a composite shield. Embodiments of the present disclosure, for example, in comparison to concepts failing to include one or more of the features disclosed herein, permit increases in shielding of electronic components, permit increased shielding effectiveness in high and low frequency ranges, permit flexibility, permit decreased resistivity, permit decreased fabrication costs, permit reduction of weight of articles including such composite shields instead of alternative shielding mechanisms, permit heat-recoverable materials to be secured without an adhesive adversely increasing resistivity, permit other suitable advantages and distinctions, and permit combinations thereof.

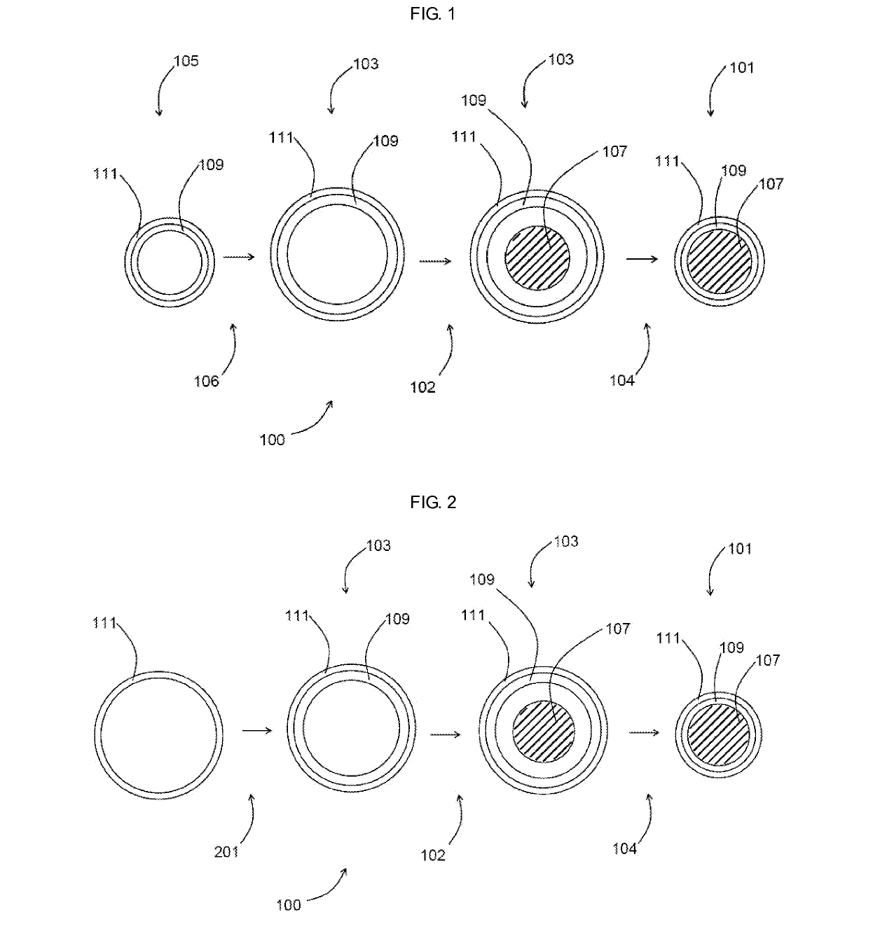

FIG. 1 shows a process 100 of producing a conductive heat-recovered composite shield 101 that forms a portion or entirety of an article, such as, a tube, a sheet, a sleeve, an end cap, a tape, another suitable heat-recovered product, or a combination thereof. As used herein, the term “shield” is intended to reference an independent structure or portion of an independent structure. It is not intended to encompass coatings or such layers positioned on another structure. The process 100 includes extruding (step 102) a conductive heat-recoverable composite shield 103, for example as in co-extruding, over a conductor 107 (such as, a wire or cable), as is illustrated by FIG. 1 or tandem-extruding 201 as is shown in FIG. 2. The conductive heat-recoverable shield 103 is capable of being heated (step 104) to produce the conductive heat-recovered composite shield 101.

In a further embodiment, the process 100 includes forming the heat-recoverable composite shield 103, for example, by electron beaming (step 106) of a precursor 105, such as, a co-extrusion (for example, a dual-wall co-extrusion of identical or similar polymeric materials having identical or similar coefficients of thermal expansion positioned as an inner layer 109 and an outer layer 111) followed by expanding the precursor 105, thereby forming the heat-recoverable composite shield 103, and the heating (step 104) that co-heats the co-extrusion without breaking. Alternatively, the precursor 105 is an injection molding, a tandem-extrusion, or an additively-produced material.

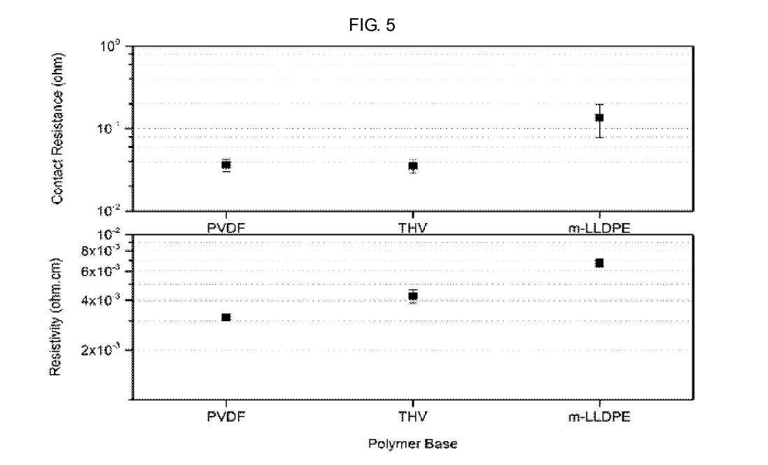

A suitable dosage for the electron beaming (step 106) is below 15 MRad. In one embodiment, the electron beaming (step 106) slightly increases crystallinity of certain polymers within the precursor 105 and, thus, slightly decreases the percolation threshold, thereby resulting in a slightly increased conductivity and shielding effectiveness for embodiments of the heat-recoverable conductive composite shield 103. For example, in one embodiment, the electron beaming (step 106) is at a dose of between 5 Mrad and 7 Mrad (for example, 6 Mrad) on polyvinylidene fluoride (PVDF). The corresponding increase in crystallinity is greater than 0.3%, greater than 0.5%, between 0.3% and 1%, between 0.5% and 1%, between 0.5% and 0.7%, or any suitable combination, sub-combination, range, or sub-range therein, for example, from 55.9% with a standard deviation of 1.1% un-beamed (302) to 56.5% with a standard deviation of 2.7% beamed (304). Referring to FIG. 4, the corresponding increase in shielding effectiveness of the heat-recoverable conductive composite shield 103 after the electron beaming is between 7 and 10 dB, for example, as tested by ASTM D4935, Standard Test Method for Measuring the Electromagnetic Shielding Effectiveness of Planar Materials.

The conductive particles of the heat-recoverable conductive composite shield 103 are or include copper particles, tin particles, nickel particles, aluminum particles, carbon particles, carbon black, carbon nanotubes, graphene, silver-coated particles, nickel-coated particles, other suitable conductive particles compatible with the non-conductive matrix, or a combination thereof. Suitable morphologies for the conductive particles include, but are not limited to, dendrites, flakes, and spheres. In one embodiment, the conductive particles are or include copper flakes and dendrites, for example, at a relative volume concentration of between 30% and 50% (for example, 40%) higher aspect ratio particles, such as copper flakes having average sizes of between 10 micrometers and 60 micrometers, and 40% and 70% (for example, 60%) lower aspect ratio particles, such as copper dendrites having average sizes of between 20 micrometers and 30 micrometers. In another embodiment, the conductive particles are or include copper dendrites, having average sizes of between 20 micrometers and 30 micrometers, at a relative volume concentration of between 40% and 70% (for example, 60%), and tin spheres, having average sizes of between 8 micrometers and 16 micrometers, at a relative volume concentration of between 30% and 50% (for example, 40%).

In one embodiment, the concentration of the conductive particles within the non-conductive matrix is above the percolation threshold, which is lower for semicrystalline polymers than amorphous polymers due to the semicrystalline polymers including more efficient filler network formation around polymer crystallites. Additionally or alternatively, in one embodiment, the concentration of the conductive particles within the non-conductive matrix is below a recrystallization-limiting threshold. As used herein, the phrase “recrystallization-limiting threshold” refers to a concentration of the conductive particles within the non-conductive matrix at which the cooling after melt-mixing during the process 100 would not permit a substantially equivalent reformation of crystals in the non-conductive matrix.

Suitable volume concentrations of the conductive particles within the non-conductive matrix include between 20% and 40% total loading, between 20% and 35% total loading, between 25% and 40% total loading, between 25% and 35% total loading, between 28% and 32% total loading, between 29% and 31% total loading, or any suitable combination, sub-combination, range, or sub-range therein.

In embodiments with the precursor 105 being the co-extrusion or the tandem-extrusion, the material of the non-conductive matrix is selected based upon tensile strength (for example, based upon ASTM D638, Standard Test Method for Tensile Properties of Plastics) and/or elongation at break. A polymer base of the conductive heat-recoverable composite shield 103 and/or the precursor 105 impacts the tensile strength at break and elongation at break.

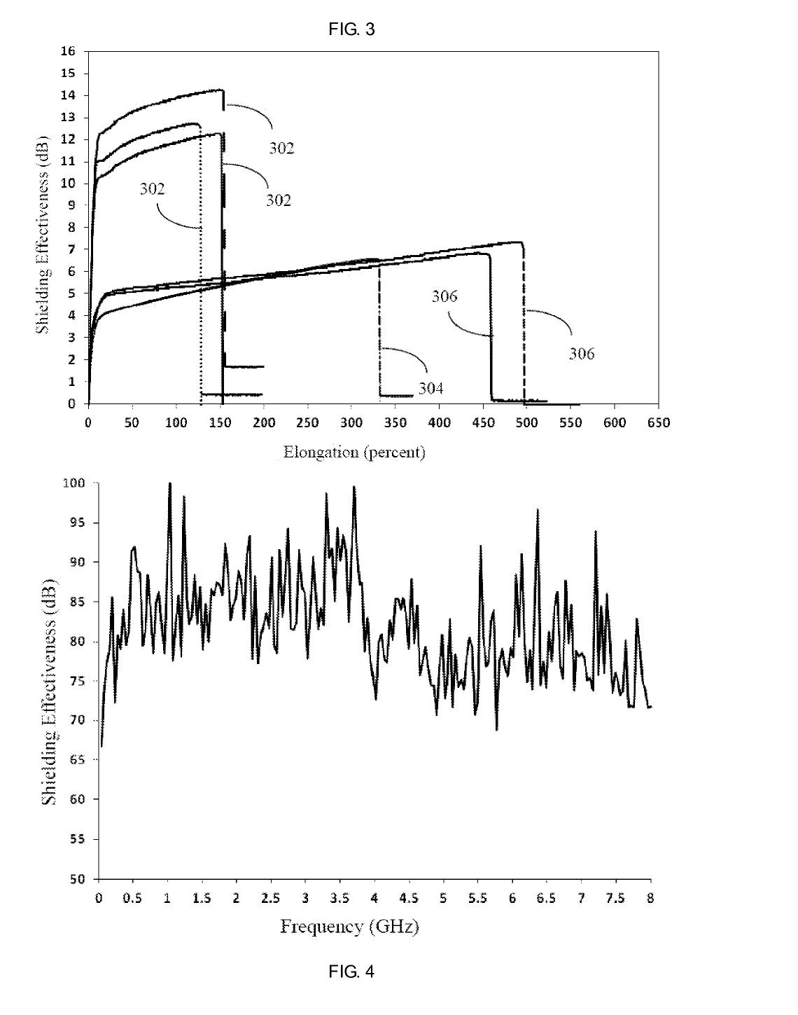

For example, in one embodiment, the PVDF is in the conductive heat-recoverable composite shield 103 and/or the precursor 105 as a polymer base, and the tensile strength at break of the heat-recoverable conductive composite shield 103 is between 10 MPa and 20 MPa (for example, between 12 MPa and 15 MPa as shown in PVDF plots 302 of FIG. 3 and/or the elongation at break is between 100% and 200% (for example, between 130% and 160% as shown in FIG. 3).

In one embodiment, tetrafluoroethylene, hexafluoropropylene and vinylidene fluoride (THV) is in the conductive heat-recoverable composite shield 103 and/or the precursor 105 as a polymer base, and the tensile strength at break of the heat-recoverable conductive composite shield 103 is between 4 MPa and 8 MPa (for example, between 6 MPa and 7 MPa as shown in THV plots 304 of FIG. 3) and/or the tensile elongation at break is between 300% and 400% (for example, between 320% and 350% as shown in FIG. 3).

In one embodiment, polyethylene (PE) (for example, linear low-density polyethylene (LLDPE)) is in the conductive heat-recoverable composite shield 103 and/or the precursor 105 as a polymer base, and the tensile strength at break of the heat-recoverable conductive composite shield is between 4 MPa and 10 MPa (for example, between 6 MPa and 8 MPa as shown in m-LLDPE plots 306 of FIG. 3) and/or the tensile elongation at break is between 400% and 600% (for example, between 450% and 500% as shown in FIG. 3).

Suitable non-conductive matrices include, but are not limited to, the PVDF, copolymers of vinylidene fluoride (VDF) and hexafluoropropylene (HFP), terpolymers of VDF, HFP and tetrafluoroethylene (TFE), fluorinated ethylene propylene, ethylene tetrafluoroethylene, polytetrafluoroethylene, other suitable fluorinated matrices compatible with the conductive particles, or a combination thereof. Other suitable non-conductive matrices include, but are not limited to the polyethylene (for example, high, medium, low, and/or linear low density polyethylene, such as, metallocene-catalyzed polyethylene (m-LLDPE)), polypropylene, ethylene-vinyl acetate, polyamide, neoprene, or a combination thereof.

In one embodiment, the non-conductive matrix has a crystallinity within a specific range, for example, between 15% and 65%, between 15% and 35%, between 15% and 20%, between 18% and 19%, between 30% and 35%, between 32% and 34%, or any suitable combination, sub-combination, range, or sub-range therein.

In addition to the non-conductive matrix and the conductive particles, the heat-recoverable conductive composite shield 103 includes any other suitable constituents. For example, in one embodiment, the heat-recoverable conductive composite shield 103 includes a sebacate-type of plasticizer, for example, at a volume concentration of between 5% and 10% (for example, 7.5%). In one embodiment, the heat-recoverable conductive composite shield 103 includes a process aid for facilitating filler dispersion and increasing processability in a homogenous or substantially homogenous manner. The heat-recoverable conductive composite shield 103 includes or is devoid of a crosslinking agent or crosslinking agents, an antioxidant, a metal deactivator, a flame retardant, and/or a coupling agent.

Suitable resistivity values of the conductive heat-recoverable composite shield 103 include being less than 0.05 ohm·cm, for example, being less than 0.01 ohm·cm, being between 0.0005 ohm·cm and 0.05 ohm·cm, or being between 0.0005 ohm·cm and 0.01 ohm·cm, depending upon the concentration of the conductive particles and the types of the non-conductive matrices. As used herein, the term “resistivity” refers to measurable values determined upon extrusion and/or full recovery and does not refer to values measured while in an expanded state. For example, FIG. 5 shows resistivity and contact resistance for embodiments of the conductive heat-recoverable composite shield 103, with the conductive heat-recoverable composite shield including the PVDF as the polymer base, THV as the polymer base, or m-LLDPE as the polymer base.

The conductive heat-recoverable composite shield 103 has a thickness, for example, of between 0.2 mm and 2 mm, 0.4 mm and 1.6 mm, 0.5 mm, 1 mm, 1.5 mm, or any suitable combination, sub-combination, range, or sub-range therein. Other suitable thickness of the conductive heat-recoverable composite shield 103 include, but are not limited to, between 0.07 mm and 0.5 mm, between 0.1 mm and 0.5 mm, between 0.2 mm and 0.5 mm, greater than 0.1 mm, greater than 0.2 mm, greater than 0.4 mm, or any suitable combination, sub-combination, range, or sub-range therein.

In one embodiment, the conductive heat-recoverable composite shield 103 is compatible with soldering. For example, the loading/concentration of the conductive particles is at a suitable amount such that soldering material, such as soldering paste, is able wet sufficiently on the conductive heat-recoverable composite shield 103, thereby permitting a suitable soldering joint to be formed.

In one embodiment, the conductive heat-recoverable composite shield 103 and, thus, the heat-recovered composite shield 101 each include the conductor 107 at least partially surrounded by the conductive heat-recoverable composite shield 101 or the conductive heat-recovered composite shield 101, a dielectric material positioned as the inner layer 109 being at least partially surrounded by the outer layer 111 of the conductive heat-recoverable composite shield 101 or the conductive heat-recovered composite shield 101, a jacket material (not shown) at least partially surrounding the outer layer 111 or the conductive heat-recoverable composite shield 101 or the conductive heat-recovered composite shield 101, or a combination thereof. In a further embodiment, the dielectric material is devoid or substantially devoid of the conductive particles and includes the same type polymer matrix material as the conductive heat-recoverable composite shield 101 or another suitable species of the polymer matrix materials.

Unlike a homogeneous metal shield, the DC resistivity of the conductive composite shield does not completely predict the shielding effectiveness of the material. These conductive composite materials typically have much greater shielding effectiveness than would be expected, especially at frequencies greater than 1 GHz. Thus, a resistivity as high as 0.05 ohm·cm compared to metals in the 1×10⁻⁶ ohm cm range, can still give adequate shielding performance. In addition, using the conductive composite shield plus a metal braided or wrapped shield is synergistic. The metal shield has good low frequency shielding (i.e. in the KHz to 1 GHz range), but shielding effectives decreases at higher frequencies. The conductive composite shields described herein tend to have the opposite behavior. In addition, combining a metal braid with a conductive composite shield allows the use of conventional connectors and termination methods.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. An article, comprising:
a conductive heat-recoverable composite shield;
wherein the conductive composite shield comprises a non-conductive matrix and conductive particles within the non-conductive matrix;
wherein the article has a resistivity of less than 0.05 ohm·cm.

2. The article of claim 1, wherein the conductive heat-recoverable composite shield has been expanded after electron beaming within a range of 3 Mrad and 15 Mrad.

3. The article of claim 1, wherein the article has a resistivity of between 0.0005 ohm·cm and 0.05 ohm·cm.

4. The article of claim 1, further comprising a conductor at least partially surrounded by the conductive heat-recoverable composite shield.

5. The article of claim 1, further comprising a dielectric material at least partially surrounded by the conductive heat-recoverable composite shield.

6. The article of claim 1, further comprising a jacket material at least partially surrounding the conductive heat-recoverable composite shield.

7. The article of claim 6, wherein the jacket and the conductive heat-recoverable composite shield are a dual-wall co-extrusion.

8. The article of claim 6, wherein the jacket and the conductive heat-recoverable composite shield are a tandem-extrusion.

9. The article of claim 1, wherein the conductive heat-recoverable composite shield is an extruded article.

10. The article of claim 1, wherein the conductive heat-recoverable composite shield is an injection molded article.

11. The article of claim 1, wherein the article is a heat-recoverable tube.

12. The article of claim 1, wherein the article is a heat-recoverable sheet.

13. The article of claim 1, wherein the article is a heat-recoverable end cap or a heat-recoverable tape.

14. The article of claim 1, wherein the conductive particles include particles selected from the group consisting of copper particles, tin particles, nickel particles, aluminum particles, carbon particles, carbon black, carbon nanotubes, graphene, silver-coated particles, nickel-coated particles, or a combination thereof.

15. The article of claim 1, wherein the conductive particles include carbon black, carbon nanotubes, graphene, or a combination thereof.

16. The article of claim 1, wherein the non-conductive matrix includes material selected from the group consisting of polyvinylidene fluoride, copolymers of vinylidene fluoride (VDF) and hexafluoropropylene (HFP), terpolymers of VDF, HFP and tetrafluoroethylene (TFE), fluorinated ethylene propylene, ethylene tetrafluoroethylene, polyethylene (PE), polypropylene, ethylene-vinyl acetate, polyamide, neoprene, and combinations thereof.

17. The article of claim 1, wherein the conductive heat-recoverable composite shield has a thickness of at least 0.07 mm.

18. An article, comprising:
a conductive heat-recovered composite shield formed from a conductive heat-recoverable composite shield;
wherein the heat-recoverable conductive composite shield comprises a non-conductive matrix and conductive particles within the non-conductive matrix;
wherein the article has a resistivity of less than 0.05 ohm·cm.

19. A process of producing a conductive heat-recovered composite shield, the process comprising:
extruding a conductive heat-recoverable composite shield; and
heating the conductive heat-recoverable composite shield thereby forming the conductive heat-recovered composite shield;
wherein the heat-recoverable conductive composite shield comprises a non-conductive matrix and conductive particles within the non-conductive matrix.

20. The process of claim 19, wherein the extruding is a co-extruding of the conductive heat-recoverable composite shield and a jacket material.
